(19) United States
(12) Patent Application Publication
(10) Pub. No.: US 2026/0293761 A1
(43) Pub. Date: Sep. 24, 2026

(54) SEMICONDUCTOR DEVICE AND SEMICONDUCTOR MEMORY DEVICE

(71) Applicant: Kioxia Corporation, Tokyo (JP)

(72) Inventors: Hideo AOKI, Yokohama (JP); Kazuma HASEGAWA, Fujisawa (JP); Tsukasa KONNO, Yokohama (JP)

(21) Appl. No.: 19/313,971

(22) Filed: Aug. 29, 2025

(30) Foreign Application Priority Data
Mar. 21, 2025 (JP) 2025-046966

(51) Int. Cl. H01L 25/18; H01L 23/00; H01L 23/373; H10B 80/00; H10D 80/30

(52) U.S. Cl. CPC H10W 90/00; H10B 80/00; H10D 80/30; H10W 40/257; H10W 72/07354; H10W 72/325; H10W 72/347; H10W 72/352; H10W 72/353; H10W 72/354; H10W 72/884; H10W 90/24; H10W 90/732; H10W 90/752; H10W 90/754; H10W 90/792

(57) ABSTRACT

A semiconductor device includes a plurality of first semiconductor chips stacked in a vertical direction; a first chip-mounted member provided between a lower one and an upper one of the first semiconductor chips; and a plurality of second semiconductor chips each provided on an upper surface of a corresponding lower one of the plurality of first semiconductor chips. The first chip-mounted member has a thermal conductive member having a thermal conductivity higher than a thermal conductivity of the second semiconductor chip.

### CROSS-REFERENCE TO RELATED APPLICATION(S)

This application is based upon and claims the benefit of priority from Japanese Patent Application No. 2025-046966, filed Mar. 21, 2025, the entire contents of which are incorporated herein by reference.

### FIELD

Embodiments described herein relate generally to a semiconductor device and a semiconductor memory device.

### BACKGROUND

Examples of a semiconductor device include one having a plurality of stacked semiconductor chips is mounted on a mounting substrate.

### DESCRIPTION OF THE DRAWINGS

FIG. 1 is a schematic diagram illustrating a cross-section parallel to a YZ plane of a semiconductor device according to a first example of a first embodiment.

FIG. 2 is a schematic diagram illustrating the details of a cross-section parallel to a YZ plane of a stacked unit according to the first example of the first embodiment.

FIG. 3 is a schematic diagram illustrating the details of a cross-section parallel to a YZ plane of a stacked unit according to the first example of the first embodiment.

FIG. 4 is a schematic diagram illustrating a cross-section parallel to a YZ plane of a semiconductor device according to a second example of the first embodiment.

FIG. 5 is a schematic diagram illustrating the details of a cross-section parallel to a YZ plane of a stacked unit according to the second example of the first embodiment.

FIG. 6 is a schematic diagram illustrating a cross-section parallel to a YZ plane of a semiconductor device according to a third example of the first embodiment.

FIG. 7 is a schematic diagram illustrating a cross-section parallel to a YZ plane of a semiconductor device according to a fourth example of the first embodiment.

FIG. 8 is a schematic diagram illustrating a cross-section parallel to a YZ plane of a semiconductor device according to a first example of a second embodiment.

FIG. 9 is a schematic diagram illustrating the details of a cross-section parallel to a YZ plane of a stacked unit according to the first example of the second embodiment.

FIG. 10 is a schematic diagram illustrating a cross-section parallel to a YZ plane of a semiconductor device according to a second example of the second embodiment.

FIG. 11 is a schematic diagram illustrating the details of a cross-section parallel to a YZ plane of a stacked unit according to the second example of the second embodiment.

FIG. 12 is a schematic diagram illustrating a cross-section parallel to a YZ plane of a semiconductor device according to a third example of the second embodiment.

FIG. 13 is a schematic diagram illustrating the details of a cross-section parallel to a YZ plane of a stacked unit according to the third example of the second embodiment.

FIG. 14 is a schematic diagram illustrating a cross-section parallel to a YZ plane of a semiconductor device according to a fourth example of the second embodiment.

FIG. 15 is a schematic diagram illustrating a cross-section parallel to a YZ plane of a semiconductor device according to a fifth example of the second embodiment.

FIG. 16 is a schematic diagram illustrating a cross-section parallel to a YZ plane of a semiconductor device according to a first example of a third embodiment.

FIG. 17 is a schematic diagram illustrating the details of a cross-section parallel to a YZ plane of a stacked unit according to the first example of the third embodiment.

FIG. 18 is a schematic diagram illustrating the details of a cross-section parallel to a YZ plane of a stacked unit according to a second example of the third embodiment.

### DETAILED DESCRIPTION

Technologies are urged to prevent temperature increases in semiconductor chips.

Embodiments provide a semiconductor device and a semiconductor memory device that can prevent temperature increases in a semiconductor chip.

In general, according to one embodiment, a semiconductor device includes a plurality of first semiconductor chips stacked in a vertical direction; a first chip-mounted member provided between a lower one and an upper one of the first semiconductor chips; and a plurality of second semiconductor chips each provided on an upper surface of a corresponding lower one of the plurality of first semiconductor chips. The first chip-mounted member has a thermal conductive member having a thermal conductivity higher than a thermal conductivity of the second semiconductor chip.

According to one embodiment, a semiconductor memory device includes the semiconductor device, in which the second semiconductor chip includes a memory circuit having a nonvolatile storage area, and the first semiconductor chip includes a control circuit for controlling the memory circuit.

Hereinafter, the present embodiments will be described with reference to the accompanying drawings. For facilitating understanding of the descriptions, same elements are denoted by same reference signs as much as possible and repetitive descriptions are omitted.

### First Embodiment

A configuration of a semiconductor device according to a first embodiment will be described below. The drawings include an X axis, a Y axis, and a Z axis. The X axis, the Y axis, and the Z axis form a right-handed three-dimensional Cartesian coordinate system. Hereinafter, the direction of the arrow along the X axis is sometimes referred to as the positive direction of the X axis, and the direction opposite to the arrow is referred to as the negative direction of the X axis. This applies to the rest of the axes. The positive direction of the Z axis and the negative direction of the Z axis are sometimes referred to as “up” and “down”, respectively. Further, the plane perpendicular to the X axis, the Y axis, or the Z axis is sometimes referred to as a YZ plane, a ZX plane, or an XY plane, respectively. The Z-axis direction is sometimes referred to as an “up-down direction”. The terms “up”, “down”, and “up-down direction” are used to indicate relative positional relationships within the drawings and are not terms that define orientations with reference to the vertical direction.

Unless otherwise specified, the dimensions and so on of the elements illustrated in the drawings may differ from the actual dimensions for ease of understanding of the description.

In the present specification, the term “connection” includes not only physical connection but also electrical connection, and includes not only direct connection but also indirect connection unless otherwise specified.

In the present specification, the term “formed above” refers not only to a case where it is formed in direct contact above but also, unless otherwise specified, includes a case where it is formed above via other elements. The same applies to the term “formed below” and so on.

Hereinafter, a description is given of a first example of a semiconductor device according to the first embodiment (sometimes referred to as the first example of the first embodiment below).

### First Example of First Embodiment

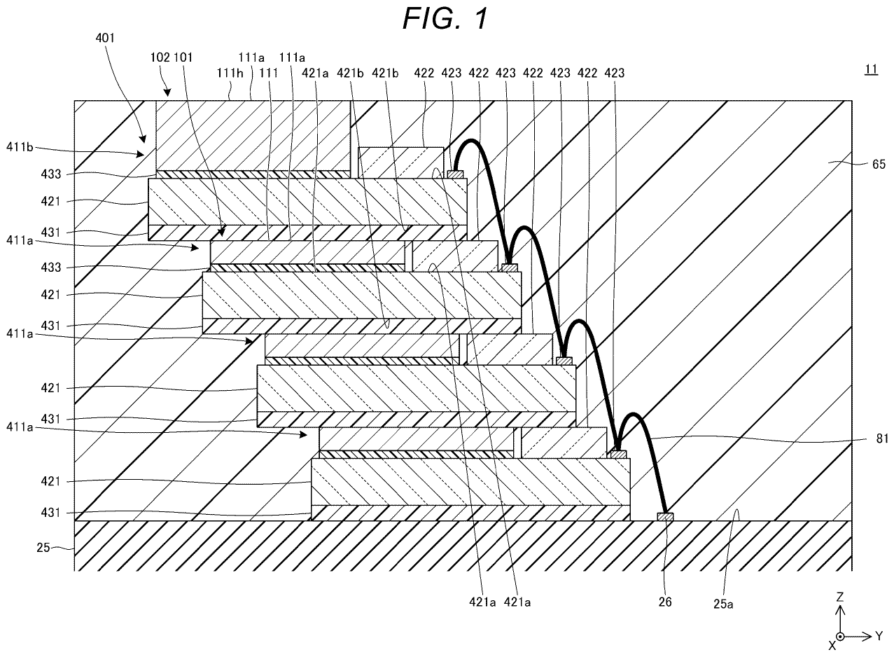

FIG. 1 is a schematic diagram illustrating a cross-section parallel to a YZ plane of a semiconductor device 11 according to the first example of the first embodiment. As illustrated in FIG. 1, the semiconductor device 11 includes a wiring board 25, a sealing resin 65, a bonding wire 81, and a stacked body 401.

The wiring board 25 has an upper surface 25a intersecting the up-down direction (Z axis direction). In the present embodiment, the upper surface 25a is substantially parallel to the XY plane. The wiring board 25 is formed with an electrode pattern (not illustrated).

A plurality of substrate electrodes 26 are provided on the upper surface 25a. The plurality of substrate electrodes 26 are arranged in a row along the X-axis direction to form a bonding finger. The bonding finger of the substrate electrodes 26 is located on the positive direction side of the Y axis of the stacked body 401.

In the first example of the first embodiment, the stacked body 401 includes three stacked units 411a and a stacked unit 411b. Hereinafter, each of the stacked units 411a and 411b is sometimes referred to as a stacked unit 411. Incidentally, the stacked body 401 may have a configuration in which two, three, five stacked units 411 or more.

The stacked body 401 is provided on the upper surface 25a of the wiring board 25. The stacked units 411a, 411a, 411a, and 411b are stacked in this order from down to up.

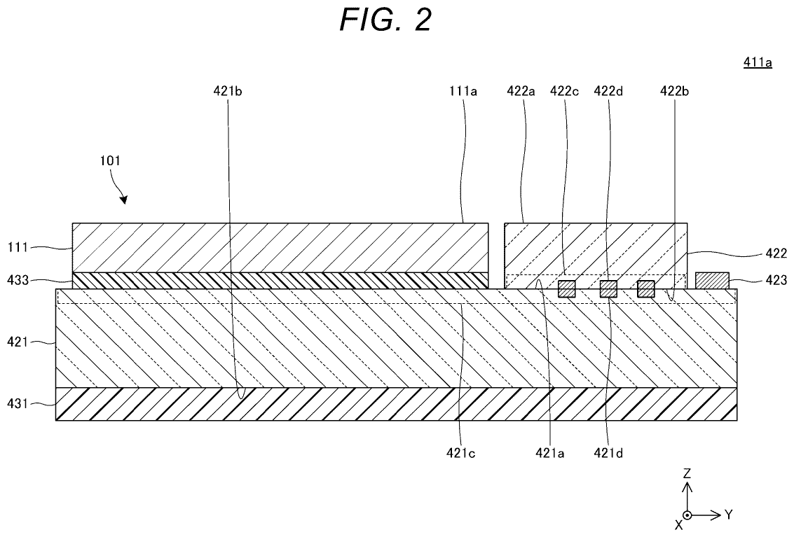

FIG. 2 is a schematic diagram illustrating the details of a cross-section parallel to a YZ plane of the stacked unit 411a according to the first example of the first embodiment. As shown in FIGS. 1 and 2, the stacked unit 411a includes a chip-mounted member 101 (an example of the “first chip-mounted member”), a CMOS (Complementary Metal-Oxide-Semiconductor) chip 421 (an example of the “first semiconductor chip”), a memory chip 422 (an example of the “second semiconductor chip”), electrode pads 423, a die-attach film 431 (an example of the “second resin layer”), and an adhesive film 433. The CMOS chip 421 and the memory chip 422 contain silicon, for example.

The memory chip 422 includes a memory circuit 422c having a nonvolatile memory area. The memory circuit 422c is a memory cell array formed on a lower surface 422b of the memory chip 422, for example. The memory circuit 422c is formed, for example, on a semiconductor substrate containing silicon.

Specifically, the memory chip 422 is a memory chip including a NAND-type flash memory. The memory circuit 422c may be a three-dimensional memory cell array with a plurality of memory cells arranged in a three-dimensional configuration.

The CMOS chip 421 includes a control circuit 421c that controls the memory circuit 422c of the memory chip 422. The control circuit 421c is, for example, a CMOS circuit formed on the upper surface 421a of the CMOS chip 421. The control circuit 421c is formed, for example, on a semiconductor substrate containing silicon. The size of the CMOS chip 421 in the Y-axis direction, namely, the width thereof, is greater than the width of the memory chip 422.

The lower surface 422b of the memory chip 422 and the upper surface 421a of the CMOS chip 421 are joined together. Specifically, a paste pad 421d (one example of a “first pad”) is provided on the upper surface 421a of the CMOS chip 421. A paste pad 422d (one example of a “second pad”) is provided on the lower surface 422b of the memory chip 422.

The paste pad 421d and the paste pad 422d are joined together, so that the CMOS chip 421 and the memory chip 422 are joined together. This allows the CMOS chip 421 and the memory chip 422 to be mechanically coupled to each other, and also allows the memory circuit 422c and the control circuit 421c to be electrically connected to each other.

The CMOS chip 421 further includes an electrode pad 423 (one example of a “bonding pad”) provided on the upper surface 421a. The number of electrode pads 423 may be the same as the number of substrate electrodes 26 forming the bonding finger. The plurality of electrode pads 423 are provided on the upper surface 421a of the CMOS chip 421 on the positive direction side of the Y axis of the memory chip 422. The plurality of electrode pads 423 are arranged in a row along the X-axis direction. The electrode pads 423 are, for example, electrically connected to the control circuit 421c.

The die attach film 431 is provided below the CMOS chip 421, and is in contact with the lower surface 421b of the CMOS chip 421. The die attach film 431 is, for example, a thermosetting resin, and is an adhesive to secure members together when heated.

The chip-mounted member 101 includes a metal plate 111 (one example of a “thermal conductive member” and an “electroconductive member”), and the adhesive film 433. The metal plate 111 is a plate-shaped member extending along the XY plane, and is provided on the memory chip 422 on the negative direction side of the Y axis.

The width of the metal plate 111 is substantially the same as the width of the adhesive film 433, for example. The width of the metal plate 111 is greater than the width of the memory chip 422. The width of the adhesive film 433 is greater than the width of the memory chip 422. The combined width of the memory chip 422 and any one of the metal plate 111 and the adhesive film 433 is smaller than the width of the CMOS chip 421.

The metal plate 111 is adhered to the upper surface 421a of the CMOS chip 421 with the adhesive film 433. The adhesive film 433 may contain a metal filler such as silver, copper, or gold in order to enhance the thermal conductivity.

The metal plate 111 has thermal conductivity higher than thermal conductivity of the die attach film 431. Preferably, the metal plate 111 has thermal conductivity higher than thermal conductivity of the memory chip 422 or the CMOS chip 421. Further, the metal plate 111 may have the thermal conductivity higher than 100 W/m/K.

Specifically, the metal plate 111 contains silver, copper, or gold, for example. Here, the thermal conductivity of silver, copper, gold, and silicon is approximately 418, 394, 320, and 168 W/m/K, respectively.

The metal plate 111 is electrically connected to a terminal to which the reference potential in the CMOS chip 421 is supplied. The reference potential is, for example, the ground potential in the control circuit 421c. The reference potential may be a power supply voltage of a transistor in the control circuit 421c such as VCC or VDD. The metal plate 111 may be electrically in a floating state.

Such a configuration enables the metal plate 111 to function as a shield layer, which reduces the influence that a noise leaking from the stacked unit 411 has on another stacked unit 411. Further, for example, the metal plate 111 can be used as a part of power wiring, which enhances the power supply.

The upper end of the metal plate 111 is aligned with the upper end of the memory chip 422. Specifically, the size of the metal plate 111 in the up-down direction, namely, the thickness thereof, plus the thickness of the adhesive film 433 is substantially equal to the thickness of the memory chip 422. Assuming that the upper surface 421a of the CMOS chip 421 is used as the reference, the height of the chip-mounted member 101 is substantially the same as the height of the memory chip 422. An upper surface 111a of the metal plate 111 and an upper surface 422a of the memory circuit 422c are substantially parallel to the XY plane. The position of the upper surface 111a in the up-down direction is substantially the same as the position of the upper surface 422a in the up-down direction.

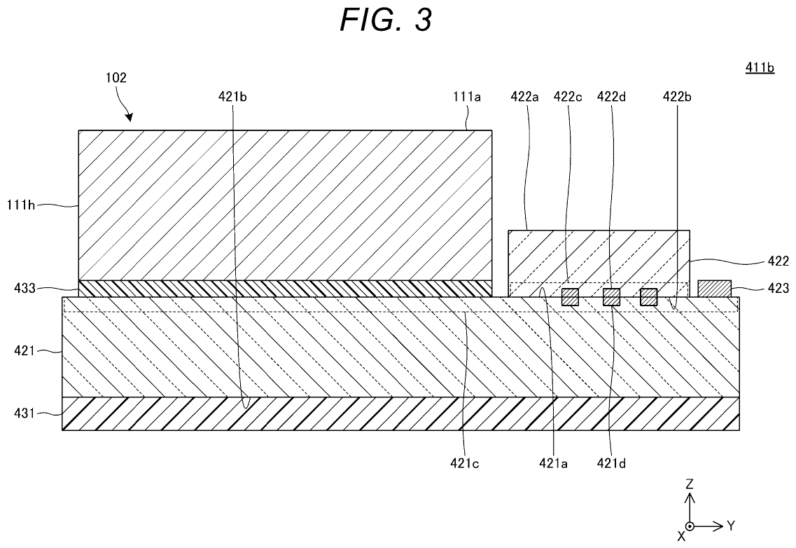

FIG. 3 is a schematic diagram illustrating the details of a cross-section parallel to a YZ plane of the stacked unit 411b according to the first example of the first embodiment. As compared with the stacked unit 411a of FIG. 2, the stacked unit 411b includes, as illustrated in FIGS. 1 to 3, a chip-mounted member 102 (one example of a “second chip-mounted member”) instead of the chip-mounted member 101.

The chip-mounted member 102 is provided on the upper surface 421a of the uppermost CMOS chip 421. The chip-mounted member 102 includes a metal plate 111h and the adhesive film 433. The metal plate 111h of the chip-mounted member 102 has a thickness greater than that of the metal plate 111 of the chip-mounted member 101.

In the stacked unit 411b, the position of the upper surface 111a of the metal plate 111h in the up-down direction is higher than the position of the upper surface 422a of the memory chip 422 in the up-down direction. Assuming that the upper surface 421a of the CMOS chip 421 is used as the reference, the height of the chip-mounted member 102 in the up-down direction is greater than the height of the memory chip 422.

In the stacked body 401, the plurality of CMOS chips 421 are stacked in the up-down direction (see FIG. 1). The chip-mounted member 101 is provided, between two CMOS chips 421 adjacent to each other (positioned next to each other) in the up-down direction, on the upper surface 421a of the lower CMOS chip 421.

The chip-mounted member 101 is connected to the lower surface 421b of the CMOS chip 421 provided above via the die attach film 431. Specifically, the upper surface of the chip-mounted member 101, namely, the upper surface 111a, comes into contact with the lower surface of the die attach film 431.

The plurality of memory chips 422 are provided on the upper surface 421a of each of the plurality of CMOS chips 421.

The wiring board 25 is provided below the CMOS chip 421 of the lowermost stacked unit 411a. The lowermost stacked unit 411a is fixed to the upper surface 25a of the wiring board 25 with the die attach film 431.

The stacked unit 411 located at the second tier from the bottom, the stacked unit 411 located at the third tier from the bottom, and the uppermost stacked unit 411 are each fixed to the stacked unit 411a located at a tier immediately below them with the die attach film 431.

The die attach film 431 in each of the stacked unit 411 located at the second tier from the bottom, the stacked unit 411 located at the third tier from the bottom, and the uppermost stacked unit 411 is in contact with the upper surface 111a of the metal plate 111 and the upper surface 422a of the memory chip 422 in the stacked unit 411a located at a tier immediately below.

The stacked body 401 has a stepped shape on the positive direction side of the Y axis and the negative direction side of the Y axis. The electrode pads 423 are positioned at step surfaces (terrace surfaces) of steps.

The bonding wire 81 electrically connects the substrate electrode 26 on the wiring board 25 and the plurality of electrode pads 423 included in the plurality of CMOS chips 421.

Specifically, the number of bonding wires 81 may be the same as the number of substrate electrodes 26 forming the bonding finger. The plurality of substrate electrodes 26 are electrically connected to the plurality of electrode pads 423 via the bonding wires 81.

The sealing resin 65 seals at least four CMOS chips 421. The metal plate 111h in the chip-mounted member 102 is exposed from the sealing resin 65.

Specifically, above the wiring board 25, the stacked body 401, excluding the upper surface 111a of the metal plate 111h in the chip-mounted member 102, is buried in the sealing resin 65. More specifically, the stacked body 401, excluding the upper surface 111a of the metal plate 111 in the chip-mounted member 102, and the upper surface 25a of the wiring board 25 are insulated and sealed with the sealing resin 65.

The sealing resin 65, the die attach film 431, and the adhesive film 433 have mutually different compositions.

### Effects

With a configuration in which the metal plate 111 with high thermal conductivity is provided between two CMOS chips 421 adjacent in the up-down direction, the thermal resistance of a heat dissipation path along the up-down direction can be reduced. Thereby, heat generated in the CMOS chip 421 that generates a lot of heat can be appropriately dissipated through the metal plate 111, and the heat supplied to the memory chip 422 can be reduced.

Further, with a configuration in which the metal plate 111 as a heat conductor extends along the XY plane, for example, the heat from a heat source can be dissipated also in a direction in the XY plane when the heat source in the CMOS chip 421 is localized. As a result, the temperature increase near the heat source can be reduced.

Further, with a configuration in which the upper surface 111a of the metal plate 111 in the uppermost stacked unit 411b is exposed from the sealing resin 65, the heat generated in the semiconductor device 11 can be dissipated to the outside of the semiconductor device 11 from the upper surface 111a. Specifically, a heat sink or a heat pipe is connected to the upper surface 111a, for example, which leads to effective heat dissipation.

Further, with a configuration in which the position of the upper surface 111a of the metal plate 111 in the up-down direction is substantially the same as the position of the upper surface 422a of the memory circuit 422c in the up-down direction, surfaces having no steps are adhered to each other, which can make the thickness of the die attach film 431 substantially uniform. This improves the adhesion of the die attach film 431.

### Second Example of First Embodiment

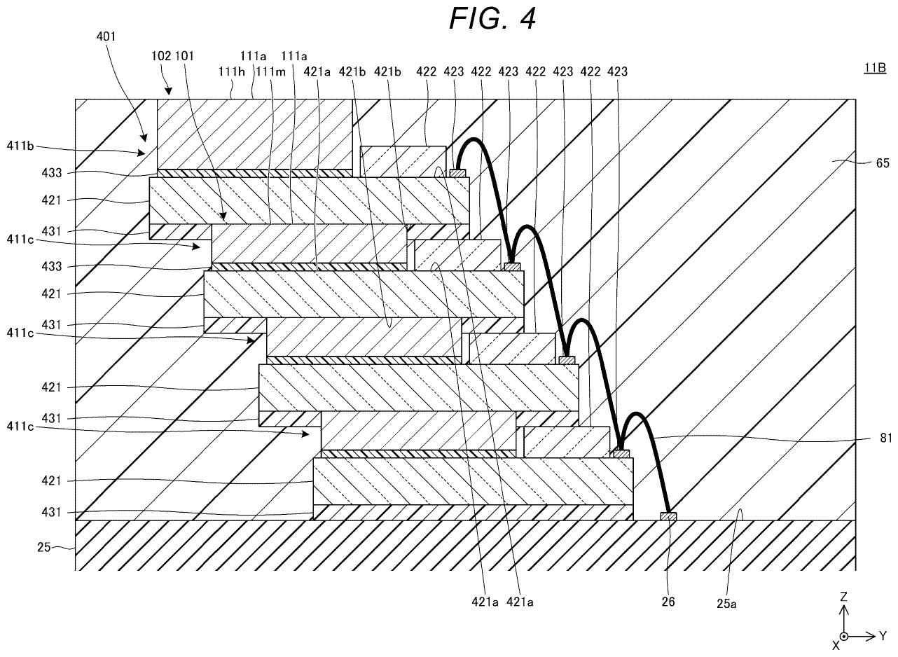

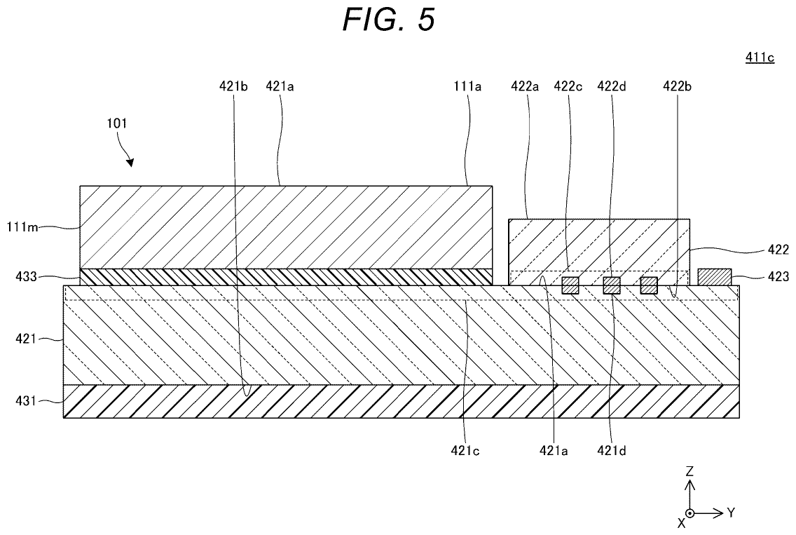

FIG. 4 is a schematic diagram illustrating a cross-section parallel to a YZ plane of a semiconductor device 11B according to a second example of the first embodiment. FIG. 5 is a schematic diagram illustrating the details of a cross-section parallel to a YZ plane of a stacked unit 411c according to the second example of the first embodiment. As illustrated in FIGS. 4 and 5, the semiconductor device 11B is different from the semiconductor device 11 according to the first example of the first embodiment illustrated in FIGS. 1 to 3 in that the metal plate passes through the die attach film 431.

As compared with the stacked body 401 illustrated in FIG. 1, in the semiconductor device 11B, the stacked body 401 includes three stacked units 411c instead of the three stacked units 411a. As compared with the stacked unit 411a illustrated in FIG. 2, the stacked unit 411c includes a metal plate 111m instead of the metal plate 111.

In the stacked unit 411c, the position of the upper end of the chip-mounted member 101 in the up-down direction, which is provided above the CMOS chip 421, is above the position of the upper end of the memory chip 422 in the up-down direction, which is provided on the upper surface 421a of the CMOS chip 421.

Specifically, the position of the upper surface 111a of the metal plate 111m in the up-down direction is above the position of the upper surface 422a of the memory chip 422 in the up-down direction. The combined thickness of the metal plate 111m and the adhesive film 433 is greater than the thickness of the memory chip 422. Assuming that the upper surface 421a of the CMOS chip 421 is used as the reference, the height of the chip-mounted member 102 is greater than the height of the memory chip 422. The difference between the position of the upper surface 111a in the up-down direction and the position of the upper surface 422a in the up-down direction, that is, the difference between the thickness (height) of the chip-mounted member 101 and the thickness (height) of the memory chip 422, is approximately equal to the thickness of the die attach film 431.

In the semiconductor device 11B, the chip-mounted member 101 comes into contact with the lower surface 421b of the CMOS chip 421 provided above. Specifically, the upper surface 111a of the metal plate 111m comes into contact with the lower surface 421b of the CMOS chip 421 in the stacked unit 411 located at a tier immediately above. Incidentally, a thin film of the die attach film 431 may be provided between the upper surface 111a of the metal plate 111m and the lower surface 421b of the CMOS chip 421.

### Effects

With a configuration in which the upper surface 111a of the metal plate 111 comes into contact with the lower surface 421b of the CMOS chip 421, the thermal resistance of the heat dissipation path along the up-down direction can be reduced.

### Third Example of First Embodiment

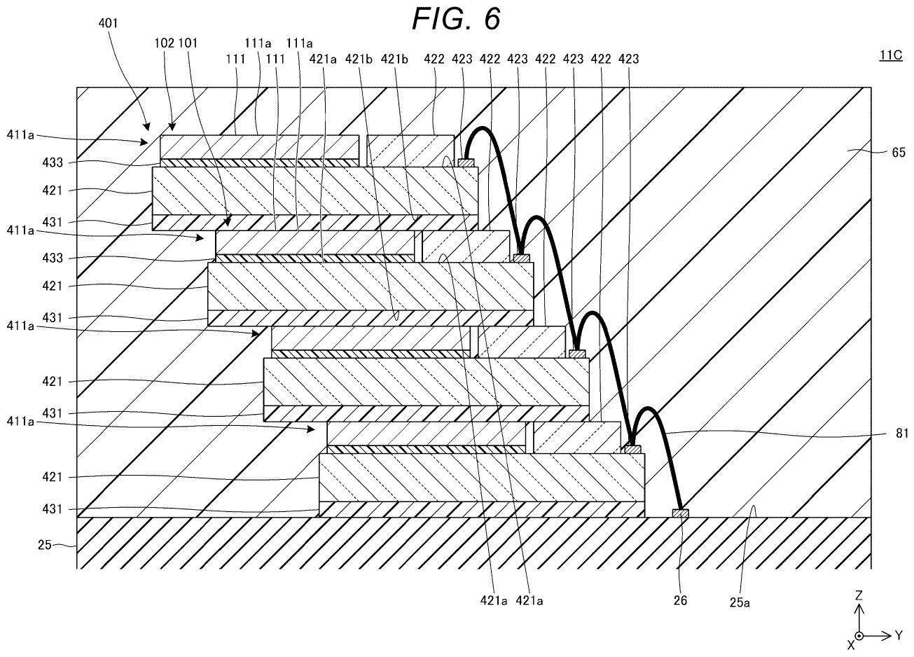

FIG. 6 is a schematic diagram illustrating a cross-section parallel to a YZ plane of a semiconductor device 11C according to a third example of the first embodiment. As illustrated in FIG. 6, the semiconductor device 11C is different from the semiconductor device 11 according to the first example of the first embodiment illustrated in FIGS. 1 to 3 in that the upper surface 111a of the metal plate 111 in the chip-mounted member 102 is not exposed from the sealing resin 65.

As compared with the stacked body 401 illustrated in FIG. 1, in the semiconductor device 11C, the stacked body 401 includes the stacked unit 411a instead of the stacked unit 411b.

In the semiconductor device 11C, above the wiring board 25, the stacked body 401 is completely buried in the sealing resin 65.

### Fourth Example of First Embodiment

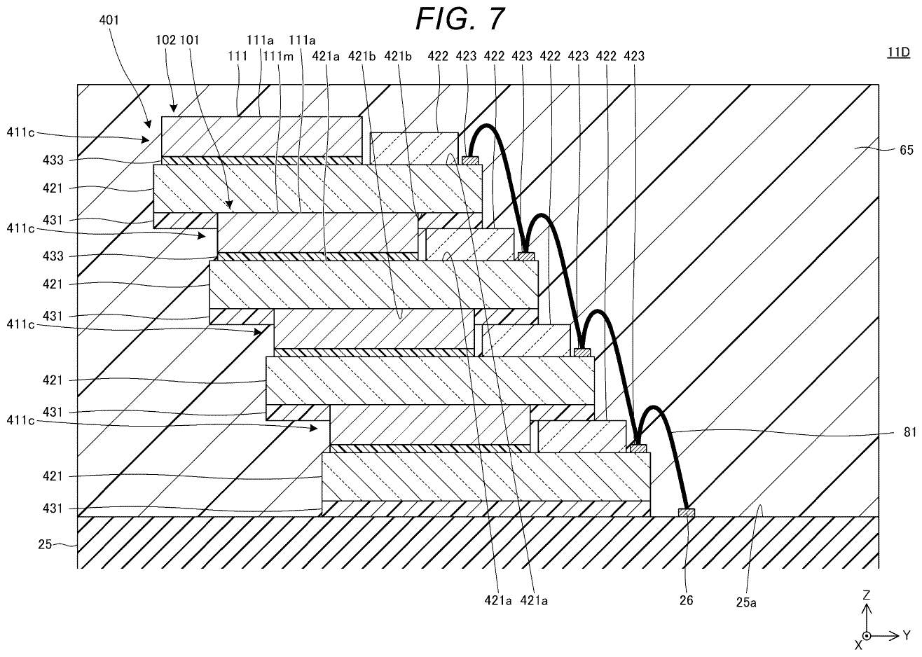

FIG. 7 is a schematic diagram illustrating a cross-section parallel to a YZ plane of a semiconductor device 11D according to a fourth example of the first embodiment. As illustrated in FIG. 7, the semiconductor device 11D is different from the semiconductor device 11B according to the second example of the first embodiment illustrated in FIGS. 4 and 5 in that the upper surface 111a of the metal plate 111 in the chip-mounted member 102 is not exposed from the sealing resin 65.

As compared with the stacked body 401 illustrated in FIG. 4, in the semiconductor device 11D, the stacked body 401 includes the stacked unit 411c instead of the stacked unit 411b.

In the semiconductor device 11D, above the wiring board 25, the stacked body 401 is completely buried in the sealing resin 65.

### Second Embodiment

A semiconductor device 12 according to a second embodiment will be described. In the second embodiment and onward, a description of the same matters as those in the first embodiment is omitted, and only the points of difference are described. In particular, similar effects and operations resulting from similar configurations are not described repeatedly for each embodiment.

### First Example of Second Embodiment

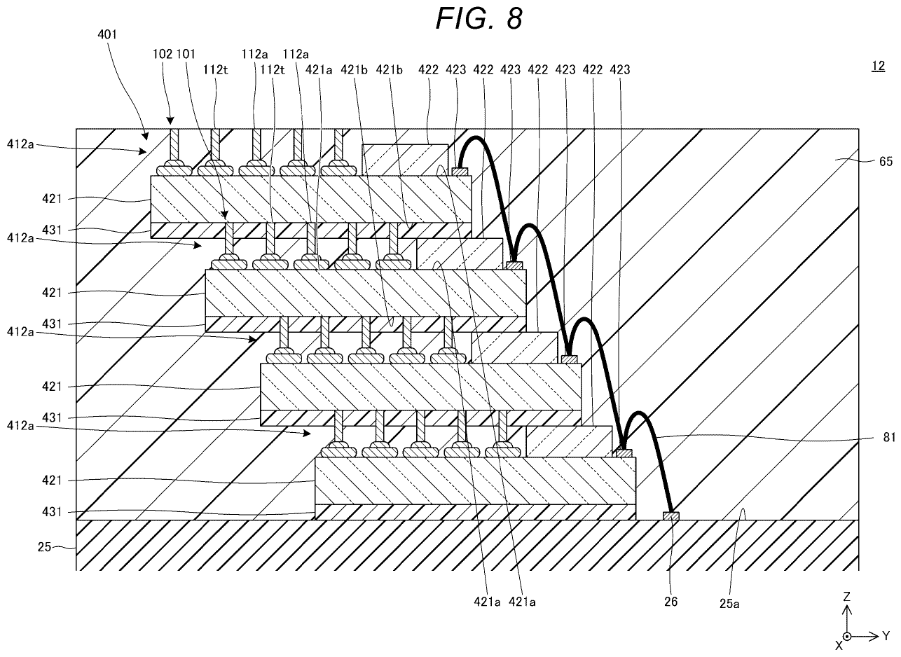

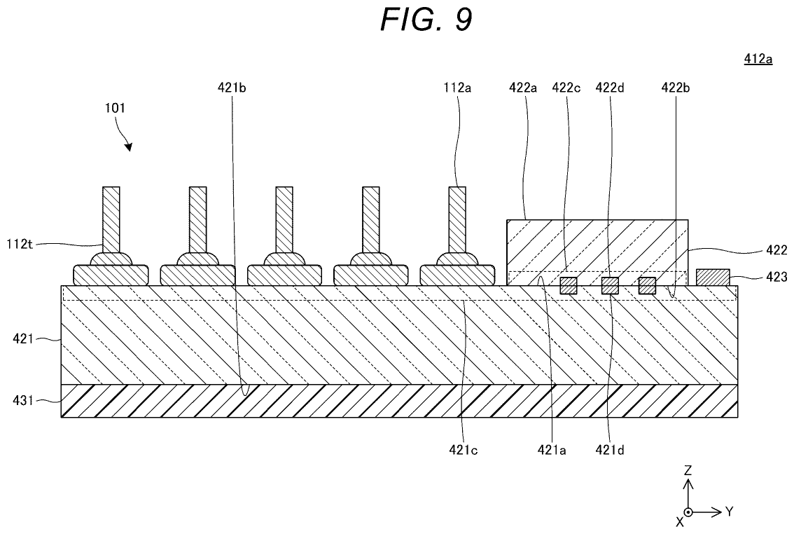

FIG. 8 is a schematic diagram illustrating a cross-section parallel to a YZ plane of the semiconductor device 12 according to a first example of the second embodiment. FIG. 9 is a schematic diagram illustrating the details of a cross-section parallel to a YZ plane of a stacked unit 412a according to the first example of the second embodiment.

As illustrated in FIGS. 8 and 9, the semiconductor device 12 according to the second embodiment is different from the semiconductor device 11 according to the first embodiment in that a plurality of columnar-shaped thermal conductive members are provided on the upper surface 421a of the CMOS chip 421.

As compared with the stacked body 401 illustrated in FIGS. 1 to 3, in the semiconductor device 12, the stacked body 401 includes four stacked units 412a instead of the four stacked units 411. Hereinafter, the stacked unit 412a is sometimes referred to as a stacked unit 412.

As compared with the chip-mounted member 101 of the stacked unit 411a illustrated in FIGS. 1 to 3, the chip-mounted member 101 of the stacked unit 412a includes a plurality of columnar portions 112t (one example of the “thermal conductive member” and the “electroconductive member”) instead of the metal plate 111 and the adhesive film 433. Hereinafter, the columnar portion 112t is sometimes referred to as a columnar portion 112.

The columnar portion 112t has thermal conductivity higher than thermal conductivity of the die attach film 431. Preferably, the columnar portion 112t has thermal conductivity higher than thermal conductivity of the memory chip 422 or the CMOS chip 421. Further, the columnar portion 112t may have the thermal conductivity higher than 100 W/m/K. Specifically, the columnar portion 112t contains a metal such as silver, copper, or gold.

The columnar portion 112t is, for example, made by aligning bonding wires to a predetermined length. The plurality of columnar portions 112t are provided on the memory chip 422 on the negative direction side of the Y axis.

The lower ends of the columnar portions 112t are in contact with the upper surface 421a of the CMOS chip 421. The columnar portions 112t extend in the up-down direction. In the present embodiment, the columnar portions 112t extend substantially parallel to the Z axis.

The position of an upper end 112a of the columnar portion 112t in the up-down direction is above the position of the upper surface 422a of the memory chip 422 in the up-down direction. Assuming that the upper surface 421a of the CMOS chip 421 is used as the reference, the height of the columnar portion 112t is greater than the height of the memory chip 422. The difference between the position of the upper end 112a in the up-down direction and the position of the upper surface 422a in the up-down direction, that is, the difference between the height of the columnar portion 112t and the height of the memory chip 422, is approximately equal to the thickness of the die attach film 431.

The chip-mounted member 101 may have a configuration in which, instead of the columnar portions 112t, the upper ends 112a of the two columnar portions 112t are bridged and a U-shaped bonding wire is included whose both ends come into contact with the upper surface 421a of the CMOS chip 421.

In the semiconductor device 12, the columnar portions 112t come into contact with the lower surface 421b of the CMOS chip 421 provided above. Specifically, the columnar portions 112t pass through the die attach film 431 in the stacked unit 412 located at a tier immediately above and come into contact with the lower surface 421b of the CMOS chip 421. Incidentally, a thin film of the die attach film 431 may be provided between the upper ends 112a of the columnar portions 112t and the lower surface 421b of the CMOS chip 421.

In the semiconductor device 12, the chip-mounted member 102 in the uppermost stacked unit 412a has the same configuration as that of the chip-mounted member 101.

The upper ends 112a of the columnar portions 112t in the chip-mounted member 102 are exposed from the sealing resin 65.

### Effects

With a configuration in which the columnar portions 112t having flexibility are provided instead of the metal plate 111, thermal stress generated in heat treatment including a temperature cycle can be reduced due to a difference between a coefficient of thermal expansion of the chip (silicon, for example) and a coefficient of thermal expansion of the columnar portions 112t (metal, for example).

With a configuration in which the columnar portions 112t pass through the die attach film 431 and the upper ends 112a of the columnar portions 112t come into contact with the lower surface 421b of the CMOS chip 421, the thermal resistance of the heat dissipation path along the up-down direction can be reduced.

### Second Example of Second Embodiment

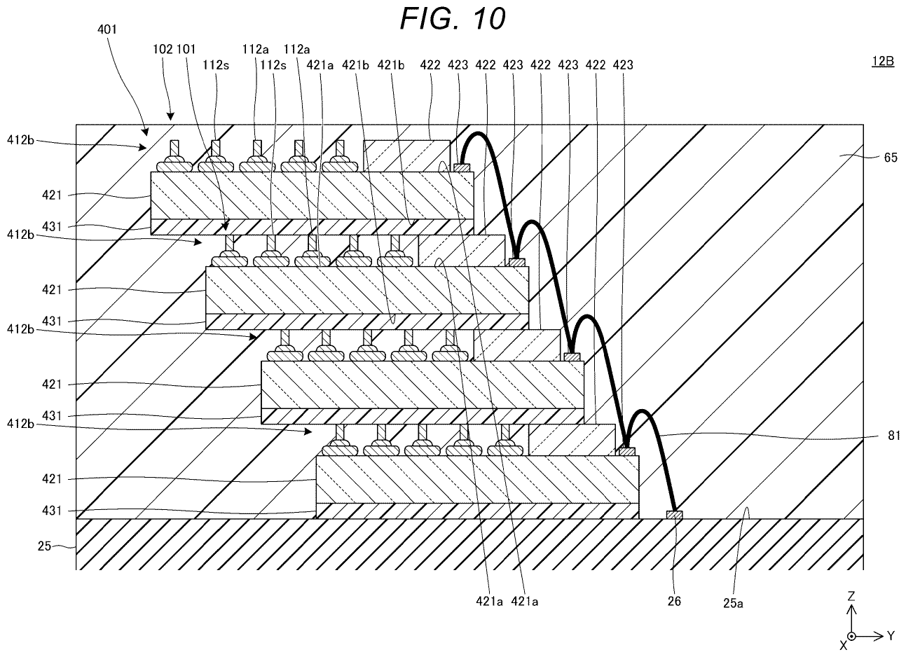

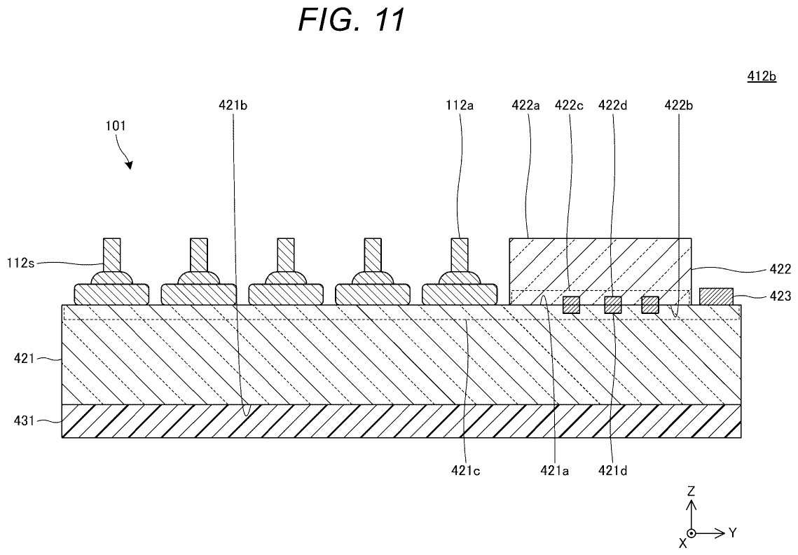

FIG. 10 is a schematic diagram illustrating a cross-section parallel to a YZ plane of a semiconductor device 12B according to a second example of the second embodiment. FIG. 11 is a schematic diagram illustrating the details of a cross-section parallel to a YZ plane of a stacked unit 412b according to the second example of the second embodiment.

As illustrated in FIGS. 10 and 11, the semiconductor device 12B is different from the semiconductor device 12 according to the first example of the second embodiment illustrated in FIGS. 8 and 9 in that the stacked body 401 includes the four stacked units 412b instead of the four stacked units 412a. The stacked unit 412b is one example of the stacked unit 412.

As compared with the chip-mounted member 101 of the stacked unit 412a illustrated in FIGS. 8 and 9, the chip-mounted member 101 of the stacked unit 412b includes a plurality of columnar portions 112s (one example of the “thermal conductive member” and the “electroconductive member”) instead of the plurality of columnar portions 112t.

The columnar portion 112s is one example of the columnar portion 112. The length of the columnar portion 112s in the up-down direction is smaller than the length of the columnar portion 112t in the up-down direction.

The position of the upper end 112a of the columnar portion 112s in the up-down direction is substantially the same as the position of the upper surface 422a of the memory chip 422 in the up-down direction. Assuming that the upper surface 421a of the CMOS chip 421 is used as the reference, the height of the columnar portion 112s is substantially the same as the height of the memory chip 422.

The die attach film 431 in each of the stacked unit 411 located at the second tier from the bottom, the stacked unit 411 located at the third tier from the bottom, and the uppermost stacked unit 411 is in contact with the upper ends 112a of the columnar portions 112s and the upper surface 422a of the memory chip 422 in the stacked unit 411 located at a tier immediately below.

In the semiconductor device 12B, the chip-mounted member 102 in the uppermost stacked unit 412b has the same configuration as that of the chip-mounted member 101.

The upper ends 112a of the columnar portions 112s in the chip-mounted member 102 are not exposed from the sealing resin 65. That is, above the wiring board 25, the stacked body 401 is completely buried in the sealing resin 65.

### Effects

With a configuration in which the upper ends 112a of the columnar portions 112s are in contact with the lower surface of the die attach film 431, it is possible to reduce physical damage to the CMOS chips 421 due to the contact between the columnar portions 112s and the CMOS chips 421.

### Third Example of Second Embodiment

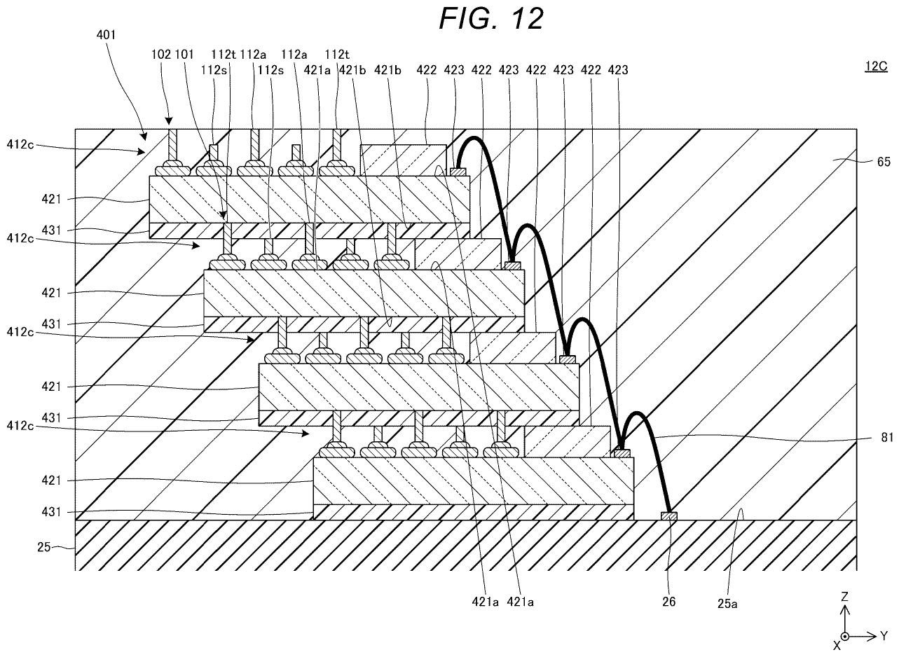

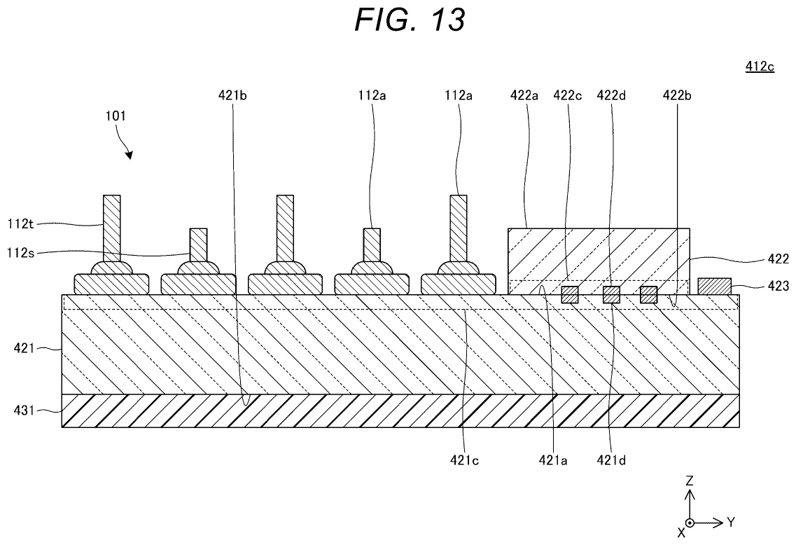

FIG. 12 is a schematic diagram illustrating a cross-section parallel to a YZ plane of a semiconductor device 12C according to a third example of the second embodiment. FIG. 13 is a schematic diagram illustrating the details of a cross-section parallel to a YZ plane of a stacked unit 412c according to the third example of the second embodiment.

As illustrated in FIGS. 12 and 13, the semiconductor device 12C is different from the semiconductor device 12 according to the first example of the second embodiment illustrated in FIGS. 8 and 9 in that the columnar portions 112t and the columnar portions 112s are installed together.

As compared with the stacked body 401 illustrated in FIGS. 8 and 9, in the semiconductor device 12C, the stacked body 401 includes four stacked units 412c instead of the four stacked units 412a. The stacked unit 412c is one example of the stacked unit 412.

As compared with the chip-mounted member 101 of the stacked unit 412a illustrated in FIGS. 8 and 9, the chip-mounted member 101 of the stacked unit 412c further includes a plurality of columnar portions 112s.

The columnar portions 112t and the columnar portions 112s are provided together on the upper surface 421a of the CMOS chip 421. In the present embodiment, the columnar portions 112t and the columnar portions 112s are arranged alternately.

In the semiconductor device 12C, the chip-mounted member 102 in the uppermost stacked unit 412c has the same configuration as that of the chip-mounted member 101.

The upper ends 112a of the columnar portions 112t in the chip-mounted member 102 are exposed from the sealing resin 65.

### Effects

With a configuration in which the columnar portions 112t and 112s are provided together on the upper surface 421a of the CMOS chip 421, it is possible to control a balance between a reduction by the columnar portions 112t in thermal resistance of the heat dissipation path along the up-down direction and a reduction by the columnar portions 112s in physical damage to the CMOS chip 421.

### Fourth Example of Second Embodiment

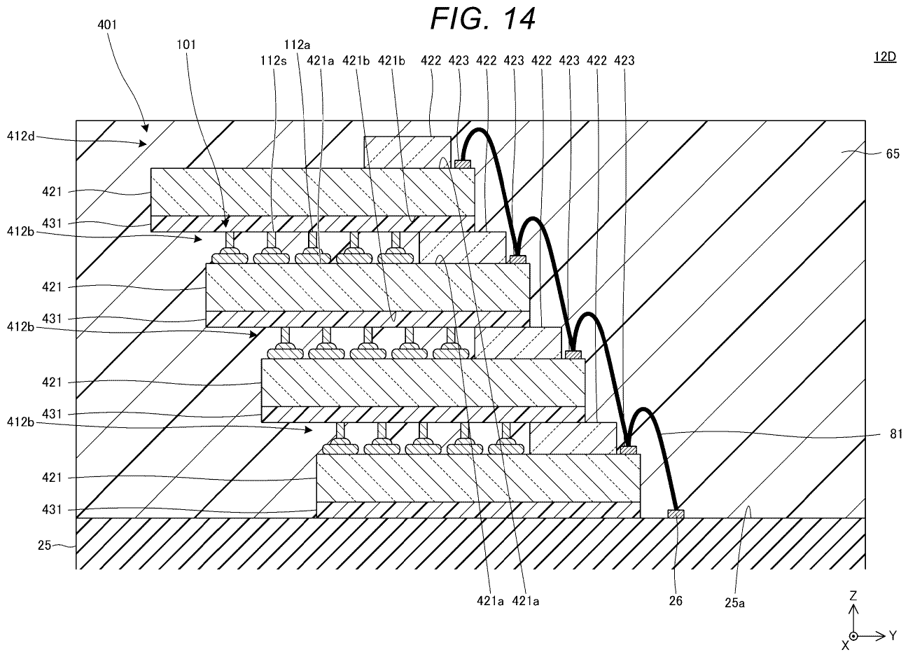

FIG. 14 is a schematic diagram illustrating a cross-section parallel to a YZ plane of a semiconductor device 12D according to a fourth example of the second embodiment. As illustrated in FIG. 14, the semiconductor device 12D is different from the semiconductor device 12B according to the second example of the second embodiment illustrated in FIGS. 10 and 11 in that no columnar portions 112s are provided on the CMOS chip 421 in the uppermost stacked unit.

As compared with the stacked body 401 illustrated in FIGS. 10 and 11, in the semiconductor device 12D, the stacked body 401 includes a stacked unit 412d instead of the uppermost stacked unit 412b. The stacked unit 412d is one example of the stacked unit 412.

As compared with the stacked unit 412b illustrated in FIGS. 10 and 11, the stacked unit 412d does not include the chip-mounted member 102.

That is, in the uppermost stacked unit 412d, no columnar portions 112 are provided on the upper surface 421a of the CMOS chip 421. Above the wiring board 25, the stacked body 401 is completely buried in the sealing resin 65.

### Effects

With a configuration in which the entirety of the stacked body 401 is covered with the sealing resin 65, a certain level of heat dissipation can be achieved and reliability such as resistance to moisture can be enhanced. Further, as compared with the semiconductor device 12B, the degree of freedom to adjust the thickness of the sealing resin 65 above the CMOS chip 421 of the stacked unit 412d can be increased, so that warpage of the semiconductor device 12D can be controlled.

Further, when a heat sink or a heat pipe is connected to the wiring board 25, for example, heat generated in the semiconductor device 12D can be dissipated to the heat sink or the heat pipe with the simple configuration.

### Fifth Example of Second Embodiment

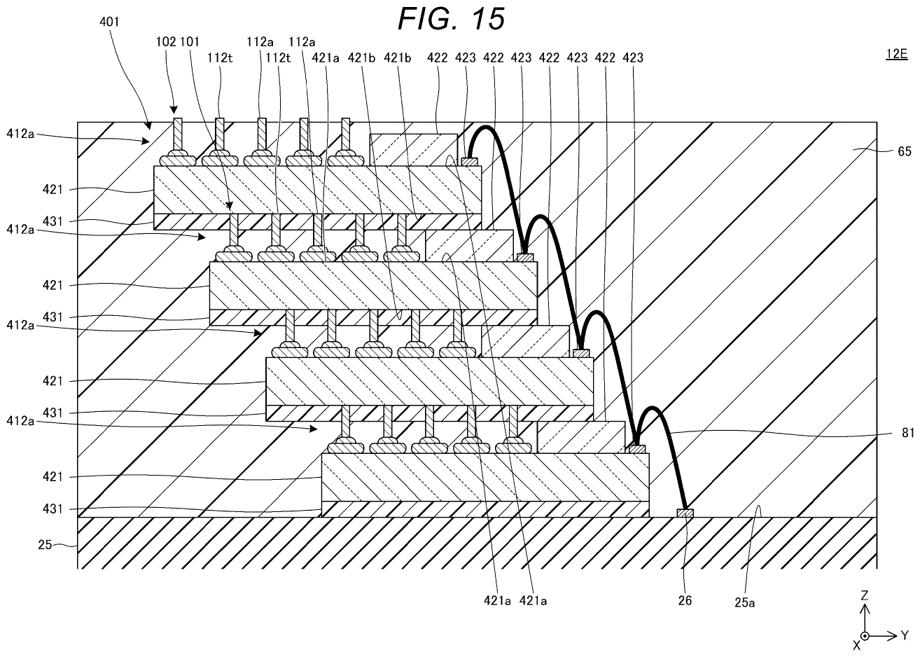

FIG. 15 is a schematic diagram illustrating a cross-section parallel to a YZ plane of a semiconductor device 12E according to a fifth example of the second embodiment. As illustrated in FIG. 15, the semiconductor device 12E is different from the semiconductor device 12 according to the first example of the second embodiment illustrated in FIGS. 8 and 9 in that upper parts of the columnar portions 112t partly protrude from the upper surface of the sealing resin 65.

The semiconductor device 12E is formed, for example, by placing a film on an inner surface of a mold used for mold formation and filling the mold with the sealing resin 65 in a state where ends of the columnar portions 112t are stuck in the film.

The upper surface of the sealing resin 65 in the semiconductor device 12E is polished, so that the semiconductor device 12 illustrated in FIG. 8 can be formed.

### Third Embodiment

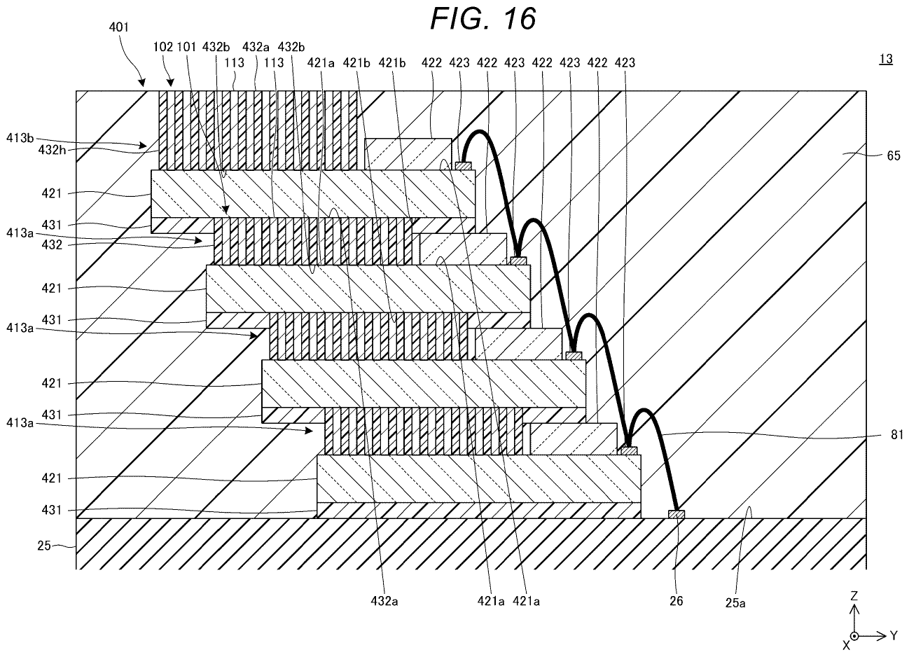

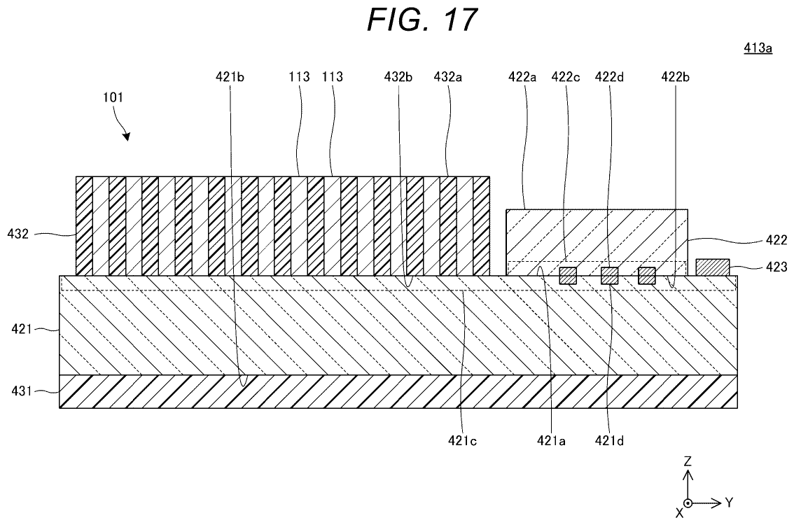

A semiconductor device 13 according to a third embodiment will be described. FIG. 16 is a schematic diagram illustrating a cross-section parallel to a YZ plane of the semiconductor device 13 according to a first example of the third embodiment. FIG. 17 is a schematic diagram illustrating the details of a cross-section parallel to a YZ plane of a stacked unit 413a according to the first example of the third embodiment.

As illustrated in FIGS. 16 and 17, the semiconductor device 13 according to the third embodiment is different from the semiconductor device 11 according to the first embodiment in that the chip-mounted members 101 and 102 include a resin layer in which a wire-like thermal conductive member is provided.

As compared with the semiconductor device 11 illustrated in FIGS. 1 to 3, in the semiconductor device 13, the stacked body 401 includes three stacked units 413a and 413b instead of the three stacked units 411a and 411b. Hereinafter, each of the stacked units 413a and 413b is sometimes referred to as a stacked unit 413.

The stacked units 413a, 413a, 413a, and 413b are stacked in this order from down to up.

As compared with the chip-mounted member 101 of the stacked unit 411a illustrated in FIGS. 1 to 3, the chip-mounted member 101 of the stacked unit 413a includes a resin layer 432 (one example of a “first resin layer”) and a plurality of columnar portions 113 (one example of the “thermal conductive member” and the “electroconductive member”) instead of the metal plate 111 and the adhesive film 433.

The columnar portions 113 have thermal conductivity higher than thermal conductivity of the die attach film 431. Preferably, the columnar portions 113 have thermal conductivity higher than thermal conductivity of the memory chip 422 or the CMOS chip 421. Further, the columnar portions 113 may have the thermal conductivity higher than 100 W/m/K.

Specifically, the columnar portions 113 contain a metal such as silver, copper, or gold, for example. Incidentally, the columnar portions 113 may include a carbon nanotube (hereinafter, sometimes referred to as a CNT). Thermal conductivity of the CNT is approximately higher than 1000 W/m/k.

The columnar portions 113 extend in the up-down direction. In the present embodiment, the columnar portions 113 extend substantially parallel to the Z axis. The resin layer 432 is penetrated by the plurality of columnar portions 113. The upper ends and lower ends of the columnar portions 113 are exposed from the upper surface 432a and the lower surface 432b of the resin layer 432, respectively.

The resin layer 432 is an elastic body or a viscoelastic body having thermoplastic properties and thermosetting properties. Modulus of elasticity of the resin layer 432 is 1 to 100 MPa, for example. As a result, the orientations of the columnar portions 113 can be achieved and the flexibility of the columnar portions 113 can be maintained. Incidentally, the modulus of elasticity of the resin layer 432 may be as large as approximately 5 GPa.

The resin layer 432 has compositions different from those of the sealing resin 65, the die attach film 431, and the adhesive film 433.

The upper surface 432a and the lower surface 432b are flat surfaces substantially parallel to the XY plane. The upper surface 432a and the lower surface 432b of the resin layer 432 are in contact with the lower surface 421b of the CMOS chip 421 provided above the resin layer 432 and the upper surface 421a of the CMOS chip 421 provided below the resin layer 432, respectively.

The position of the upper surface 432a of the resin layer 432 in the up-down direction is above the position of the upper surface 422a of the memory chip 422 in the up-down direction. The resin layer 432 has a thickness greater than a thickness of the memory chip 422. Assuming that the upper surface 421a of the CMOS chip 421 is used as the reference, the resin layer 432 is higher than the memory chip 422. The difference between the position of the upper surface 432a in the up-down direction and the position of the upper surface 422a in the up-down direction, that is, the difference between the thickness (height) of the resin layer 432 and the thickness (height) of the memory chip 422, is approximately equal to the thickness of the die attach film 431.

The resin layer 432 passes through the die attach film 431 in the stacked unit 413 located at a tier immediately above and comes into contact with the lower surface 421b of the CMOS chip 421. Incidentally, a thin film of the die attach film 431 may be provided between the upper surface 432a of the resin layer 432 and the lower surface 421b of the CMOS chip 421.

In other words, two CMOS chips 421 adjacent in the up-down direction are adhered to each other with the resin layer 432.

As compared with the chip-mounted member 101 of the stacked unit 413a, the chip-mounted member 102 of the stacked unit 413b includes a resin layer 432h instead of the resin layer 432.

The resin layer 432h of the chip-mounted member 102 has a thickness greater than that of the resin layer 432 of the chip-mounted member 101. Assuming that the upper surface 421a of the CMOS chip 421 is used as the reference, the height of the resin layer 432 is greater than that of the memory chip 422. The rest of the configuration of the resin layer 432h is similar to the configuration of the resin layer 432.

### Effects

As compared with the semiconductor device 12, the resin layer 432 having compositions different from those of the sealing resin 65 can be provided between two CMOS chips 421 adjacent to each other in the up-down direction.

For example, the resin layer 432 having flexibility can be provided between the two CMOS chips 421 adjacent to each other in the up-down direction. This increases the flexibility of the stacked body 401, which prevents the CMOS chip 421 from breaking at the time of assembly.

Further, the configuration in which a glass transition temperature Tg of the resin layer 432 is adjusted or the resin layer 432 having thermoplastic properties is used, which can soften the resin layer 432 due to an increase in temperature.

The stacked body 401, excluding the upper surface 432a of the resin layer 432h in the chip-mounted member 102, and the upper surface 25a of the wiring board 25 are insulated and sealed with the sealing resin 65.

### Second Example of Third Embodiment

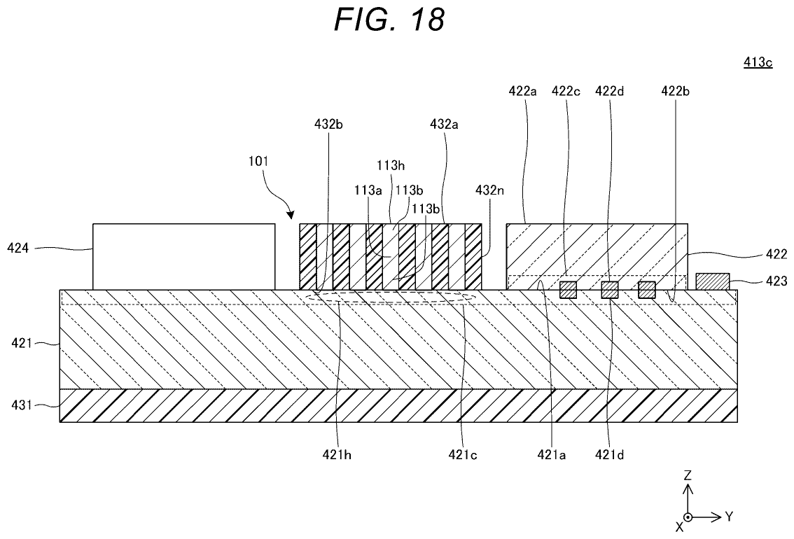

FIG. 18 is a schematic diagram illustrating the details of a cross-section parallel to a YZ plane of a stacked unit 413c according to a second example of the third embodiment. As illustrated in FIG. 18, the stacked unit 413c is different from the stacked unit 413a of the first example of the third embodiment illustrated in FIG. 17 in that the size of the resin layer 432 is reduced and other components are mounted in the available space.

As compared with the stacked unit 413a illustrated in FIG. 17, the stacked unit 413c includes a resin layer 432n and a device 424 instead of the resin layer 432.

As compared with the resin layer 432 illustrated in FIG. 17, the resin layer 432n is penetrated by a plurality of columnar portions 113h instead of the plurality of columnar portions 113.

The control circuit 421c of the CMOS chip 421 includes a heat-generating portion 421h. The heat-generating portion 421h may be a step-up circuit.

The resin layer 432n is provided above the heat-generating portion 421h. The width of the resin layer 432n in the Y-axis direction is smaller than the width of the resin layer 432 in the Y-axis direction. Each of the width of the resin layer 432n and the width of the device 424 is substantially the same as the width of the memory chip 422, for example. Each of the width of the resin layer 432n and the width of the device 424 is smaller than the width of the CMOS chip 421. The columnar portion 113h includes a metal portion 113a (one example of a “first portion”) and a CNT portion 113b (one example of a “second portion”).

The upper end of the chip-mounted member 101 is aligned with the upper end of the memory chip 422. Specifically, the thickness of the chip-mounted member 101 is substantially the same as the thickness of the memory chip 422. Assuming that the upper surface 421a of the CMOS chip 421 is used as the reference, the height of the chip-mounted member 101 is substantially the same as the height of the memory chip 422. The upper surface 432a of the resin layer 432n and the upper surface 422a of the memory circuit 422c are substantially parallel to the XY plane. The position of the upper surface 432a in the up-down direction is substantially the same as the position of the upper surface 422a in the up-down direction.

The metal portion 113a contains a metal such as gold, silver, and copper. The CNT portion 113b is provided between the metal portion 113a and the CMOS chip 421. The CNT portion 113b includes a CNT. With a configuration in which the CNT portion 113b is provided at each end of the columnar portion 113h, the CMOS chip 421 and the CNT can be brought into contact with each other. As a result, the heat contact resistance between the CMOS chip 421 and the columnar portion 113h can be reduced.

The device 424 is a chip including an active element or a passive element, or, alternatively, both of them. The device 424 is provided on the negative direction side of the Y axis of the resin layer 432n. The device 424 is adhered to the upper surface 421a of the CMOS chip 421.

In the semiconductor device 13, the stacked unit 413c may be provided instead of at least one of the stacked units 413a and 413b.

The description is given of the configuration of the semiconductor device 11 in which the stacked unit 411 is placed to extend over the upper surface 422a of the memory chip 422 and the upper surface of the chip-mounted member 101 in the stacked unit 411 provided below; however, the present disclosure is not limited thereto. The stacked unit 411 may be configured to be placed on the upper surface of the chip-mounted member 101.

As for the above description of the embodiments, the following appendices are further disclosed.

### Appendices

(a) A semiconductor device including:
a plurality of first semiconductor chips stacked in an up-down direction;
a first chip-mounted member provided, between two of the first semiconductor chips adjacent to each other in the up-down direction, on an upper surface of the first semiconductor chip located below; and
a plurality of second semiconductor chips provided on an upper surface of each of the plurality of first semiconductor chips, in which
the first chip-mounted member has a thermal conductive member having thermal conductivity higher than thermal conductivity of the first semiconductor chip.

(b) A semiconductor device including:
a plurality of first semiconductor chips stacked in an up-down direction;
a first chip-mounted member provided, between two of the first semiconductor chips adjacent to each other in the up-down direction, on an upper surface of the first semiconductor chip located below; and
a plurality of second semiconductor chips provided on an upper surface of each of the plurality of first semiconductor chips, in which
the first chip-mounted member has a thermal conductive member having thermal conductivity higher than 100 W/m/K.

(c) A semiconductor device including:
a plurality of first semiconductor chips stacked in an up-down direction;
an electroconductive member provided between two of the first semiconductor chips adjacent to each other in the up-down direction; and
a plurality of second semiconductor chips provided on an upper surface of each of the plurality of first semiconductor chips, in which
the electroconductive member has thermal conductivity higher than thermal conductivity of the second semiconductor chip.

(d) A semiconductor device including:
a plurality of first semiconductor chips stacked in an up-down direction;
a second resin layer in contact with a lower surface of the first semiconductor chip;
a first chip-mounted member provided, between two of the first semiconductor chips adjacent to each other in the up-down direction, on an upper surface of the first semiconductor chip located below; and
a plurality of second semiconductor chips provided on an upper surface of each of the plurality of first semiconductor chips, in which
the first chip-mounted member has a thermal conductive member having thermal conductivity higher than thermal conductivity of the second resin layer.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a plurality of first semiconductor chips stacked in a vertical direction;
a first chip-mounted member provided between a lower one and an upper one of the first semiconductor chips; and
a plurality of second semiconductor chips each provided on an upper surface of a corresponding lower one of the plurality of first semiconductor chips, wherein
the first chip-mounted member has a thermal conductive member having a thermal conductivity higher than a thermal conductivity of the second semiconductor chip.

2. The semiconductor device according to claim 1, wherein
the thermal conductive member is a metal plate.

3. The semiconductor device according to claim 1, wherein
the thermal conductive member includes a columnar portion extending along the vertical direction.

4. The semiconductor device according to claim 3, wherein
the columnar portion includes a metal.

5. The semiconductor device according to claim 3, wherein
the columnar portion includes a carbon nanotube.

6. The semiconductor device according to claim 3, wherein
the columnar portion includes:
a first portion including a metal, and
a second portion provided between the first portion and the lower first semiconductor chip and including a carbon nanotube.

7. The semiconductor device according to claim 3, wherein
the first chip-mounted member further includes a first resin layer, with the columnar portion penetrating therethrough.

8. The semiconductor device according to claim 7, wherein
an upper surface and a lower surface of the first resin layer are in contact with a lower surface of the upper first semiconductor chip and an upper surface of the lower first semiconductor chip, respectively.

9. The semiconductor device according to claim 1, wherein
the first chip-mounted member is in contact with a lower surface of the upper first semiconductor chip.

10. The semiconductor device according to claim 1, wherein the first chip-mounted member is connected to a lower surface of the upper first semiconductor chip via a second resin layer.

11. The semiconductor device according to claim 1, wherein an upper end of the first chip-mounted member, provided above the lower first semiconductor chip, and an upper end of the second semiconductor chip, provided above the lower first semiconductor chip, are aligned with each other.

12. The semiconductor device according to claim 1, wherein an upper end of the first chip-mounted member, provided above the lower first semiconductor chip, is above an upper end of the second semiconductor chip, provided above the lower first semiconductor chip.

13. The semiconductor device according to claim 2, wherein the metal plate is electrically connected to a terminal to which a reference potential in the first semiconductor chip is supplied.

14. The semiconductor device according to claim 2, wherein the metal plate is electrically in a floating state.

15. The semiconductor device according to claim 1, further comprising:
a sealing resin that seals at least the plurality of first semiconductor chips, and
a second chip-mounted member provided on an upper surface of a topmost one of the first semiconductor chips, wherein the second chip-mounted member is exposed from the sealing resin.

16. The semiconductor device according to claim 1, further comprising:
a plurality of bonding pad provided on upper surfaces of the first semiconductor chips, respectively,
a wiring board provided below a bottommost one of the first semiconductor chips, and
a plurality of bonding wires that connect the plurality of bonding pads to each other, and one of the bonding wires connects a corresponding one of the bonding pads to the wiring board.

17. The semiconductor device according to claim 1, wherein a first pad is provided on the upper surface of the lower first semiconductor chip, a second pad is provided on a lower surface of the corresponding second semiconductor chip, and the first pad and the second pad are joined together to bond the lower first semiconductor chip and the corresponding second semiconductor chip.

18. The semiconductor device according to claim 1, wherein the second semiconductor chips each include a memory circuit having a nonvolatile storage area, and
the first semiconductor chips each include a control circuit for controlling the corresponding memory circuit.
